(19) United States
(12) Patent Application Publication
(10) Pub. No.: US 2024/0305129 A1
(43) Pub. Date: Sep. 12, 2024

(54) Portable Power Station with Detachable DC Power Source

(71) Applicant: Xiamen Came Technology Co., Ltd., Xiamen (CN)

(72) Inventors: Hongsheng WEI, Xiamen (CN); Jinqing ZHAN, Xiamen (CN); Wanguo LIU, Xiamen (CN); Huitong SONG, Xiamen (CN)

(21) Appl. No.: 18/118,133

(22) Filed: Mar. 7, 2023

(51) Int. Cl. H02J 9/06; H02J 7/00; H02M 7/48; H05K 7/20

(52) U.S. Cl. CPC H02J 9/061; H02J 7/0044; H02J 9/062; H02M 7/48; H05K 7/20909

(57) ABSTRACT

A portable power station includes a reinforcing support frame to support a DC/AC conversion arrangement thereon and at least a DC power source thereunder so that the DC power supplied by the DC power source is converted to AC power by the DC/AC conversion arrangement, such that the DC power source is detachable and replaceable provide both low voltage DC and high voltage AC uninterrupted power supply.

### NOTICE OF COPYRIGHT

A portion of the disclosure of this patent document contains material which is subject to copyright protection. The copyright owner has no objection to any reproduction by anyone of the patent disclosure, as it appears in the United States Patent and Trademark Office patent files or records, but otherwise reserves all copyright rights whatsoever.

### BACKGROUND OF THE PRESENT INVENTION

### Field of Invention

The present invention relates to portable power supply, and more particularly to a portable power station equipped with detachable and replaceable DC power sources to provide both low voltage direct current (DC) and high voltage alternating current (AC) uninterrupted power supply.

### Description of Related Arts

Portable power station is a good solution to a workplace or outdoor environment that do not provide AC power supply through stationary power sockets. For example, to the builders of a construction site, the portable power station could be the only power supply to the power machines or power tools of the builders. Portable power station is also excellent to gardeners, campers, hunters and fishers whose gardening, camping, hunting and fishing activities are carried in outdoor, open country, jungle, riverside and seaside to supply electric power for power tools and practical usages such as cooking, lighting and the like. Even for home activities, outdoor activities are often held outdoor, for examples park, back yard, field, swimming poolside, and etc., that requires electric power for heaters, fans, lightings, electric cooking utensils, and the like, while the indoor power supply is distanced from the activity site. The portable power station allows the users to avoid lengthened extension cords and sockets that not only is inconvenience to both the host and the guests, but also cause hazards of short circuits in household power.

Conventional electric energy source, such as U.S. Pat. No. 7,511,451, generally includes a portable enclosure A1 that houses one or more built-in battery packs A2, at least one battery charger A3, at least one AC inverter A4 and a control circuit A5 configured to operate the batteries A2 and AC inverters A4, as shown in FIGS. 1A and 1B. The portable enclosure A1 includes a rigid framework A11 to support the batteries A2, the charger A3, the inverter A4 and the control circuit A5 rendering the conventional electric energy source bulky and heavy for storage and transportation. In addition, in order to dissipate the heat generated from the inverter A4 during the conversion of low voltage DC power to high voltage AC power, many electric fans A6 have to be installed in multiple positions to avoid the heat adversely affecting the performance and life span of the batteries A2, that further requires a reinforced framework A11 to support the fans A6 in various positions and increases the overall weight of the electric energy source. Since the power supply of such electric energy source is the DC batteries A2, the more batteries A2 contained in the enclosure A1 can provide longer period of power supplying time before a relatively long charging time, generally may require couple hours, to charge the batteries A2. Therefore, the conventional energy source is portable by including a pair of wheels A7 since it may be too heavy for hand carry by the user.

In order to ensure better heat dissipation effect for the inverter A4 and the control circuit A5 to avoid the great amount of heat generated during the DC/AC current conversion reducing the performance and life span of the batteries A2, the batteries A2 are preferred to be spacedly mounted in position from the inverter A4 and the control circuit A5 for a reasonable distance that further ensures the conventional electric energy source to have a compact size for storage and transportation.

In addition, the major weight of a power station is the heavy batteries, especially the carbonic acid battery that requires relatively more charging time to recharge too. The more batteries contained in a power station, the less portable the power station. Therefore, a 200-300 W power station with built-in lithium battery 280 Wh/75000 mAh is a common portable size and weight for the user to hand carry and storage in the trunk of a vehicle for emergency use. An example of such lithium battery power station is illustrated in FIG. 2, which generally can provide roughly less than 9-10 hours for DC power supply and 2-3 hours for high voltage AC power supply. The lithium batteries B1, the rectifier and inverter circuit board B2 are all enclosed and supported by the strengthen rigid casing B3. It requires a 100˜240V wall outlet to recharge for generally overnight. A 1000 W or more portable power station can provide up to 10 hours AC power supply, depending on the output power, for example, a 1800 W portable power station can supply 40 W outputs for 40 hours, a 50 W ceiling fan for 30 hours, a 60 W laptop for 25 hours, a 200 W household refrigerator for 6.5 hours, a 600 W coffee machine for 2 hours, a 900 W microwave for 1.5 hours, a 1600 W hair dryer for 0.9 hour, and etc. . . . Such heavy-duty power station weighs 40 pounds or more and requires more time to recharge. Practically speaking, the portability of such heavy duty power station is significantly reduced and should not consider portable even though a pair of wheels are provided.

In effect, a portable power station is a large-capacity battery that even the best portable power station will run out of power, unlike a generator, which will continue to provide the same level of power as long as there is running with gaseous supplied.

A power station, patent number U.S. Pat. No. 10,923,933, discloses a power station including an inverter for converting a direct current outputted by one or more battery packs into an alternating current and a rectifier for converting an alternating current into a direct current for charging the one or more battery packs. As shown in FIG. 3, the battery packs C11, C12 are self-casing and mounted to two sides of the housing C2 which houses the inverter and rectifier therein that provides a compact arrangement. However, the battery packs C11, C12 also block the heating dissipation of the electrical components housed in the housing C2 and absorbs most amount of heat generated from the inverter and rectifier housed in the housing C2 that significantly reduce the life span and performance of the batteries C11, C12. Similarly, the heat generated during the discharging of electric powers of the batteries C11, C12 is transmitted to that housing C2 that adversely affects the performance of the DC/AC conversion of the electric circuits too.

### SUMMARY OF THE PRESENT INVENTION

The invention is advantageous in that it provides a portable power station that is configured to provide uninterrupted DC and/or AC power supply with compact size and light weight for ease of storage and transportation.

Another advantage of the invention is to provide a portable power station which is arranged to provide an upper chamber for installing the heat generating electrical components and an insulated lower chamber for detachably mounting two or more DC power banks therein, so as to facilitate heat dissipation conforming to the fluid dynamics phenomenon.

Another advantage of the invention is to provide a portable power station with detachable DC power source without enclosure housing, that simplifies the supporting configuration by a reinforcing support frame to mainly support the weight of the detachable DC power source and other electrical components so as to minimize the weight and size of the portable power station.

Another advantage of the invention is to provide a portable power station having compact size and light weight, wherein the DC/AC conversion arrangement and the detachable batteries share the same reinforcing support frame to minimize an overall weight and the installation space of the portable power station while ensuring an adequate and appropriate heat dissipation arrangement.

Another advantage of the invention is to provide an insulation layer for the portable power station to isolate the heat generating DC/AC conversion arrangement from the DC power source.

Another advantage of the invention is to provide a portable power station with detachable DC power source, which enables the user to detach and replace desired power source with predetermined power supply according to his or her actual need and usage environment so as to ensure the portable power station functioning effectively and efficiently with weight as light as possible.

Another advantage of the invention is to provide a portable power station with detachable DC power source, wherein the total power supply of the detachable DC power source is capable of being determined and assembled by the user.

Another advantage of the invention is to provide a portable power station with detachable DC power source, wherein the detachable DC power source is chargeable when the portable power station is connected to an external power source.

Another advantage of the invention is to provide a portable power station with detachable DC power source, wherein the detachable DC power source is replaceable before or after it is completely drained out of power.

Another advantage of the invention is to provide a portable power station with detachable DC power source, wherein a temporary power supply is provided during the replacement of the detachable DC power source.

Another advantage of the invention is to provide a portable power station which defines a DC power chamber positioned opposing to a direction of the heat flow of the heat generated during operation of the DC/AC conversion arrangement.

Another advantage of the invention is to provide a portable power station which defines a DC/AC conversion chamber for accommodating the DC/AC conversion arrangement that enables the heat flow to outside in a shortest path.

Another advantage of the invention is to provide a portable power station with detachable DC power source, wherein only one side of the detachable DC power source and one side of the DC/AC conversion arrangement are facing each other so as to reduce the heat transfer of the DC/AC conversion arrangement to the detachable DC power source.

Another advantage of the invention is to provide a portable power station with detachable DC power source, wherein both the DC and AC power output sockets on the same side of the portable power station in a convenient manner while the DC power output terminals and AC power output sockets are thermally isolated to prevent the heat generated at the AC power output terminals during electrical connection with external electrical appliances transferring to the detachable DC power source and the DC power output terminals.

Another advantage of the invention is to provide a portable power station with detachable DC power source, which allows the user to conveniently operate and control at the same side of the portable power station.

Another advantage of the invention is to provide a portable power station with detachable DC power source, which minimizes the number of parts thereof to not only facilitate assembling and disassembling for maintenance but also reduce the weight and size thereof.

Another advantage of the invention is to provide a portable power station with detachable DC power source, which allows the user to hand carry in a balanced manner for ease of transportation.

Another advantage of the invention is to provide a portable power station with detachable DC power source, which is compact in size while maintaining adequate heat dissipation to ensure normal operation of the detachable DC power source and the DC/AC conversion arrangement for ease of storage and transportation.

Another advantage of the invention is to provide a portable power station with detachable DC power source, wherein the one or more power banks of the detachable DC power source are able to be detached for independent usage or charging.

Another advantage of the invention is to provide a portable power station with detachable DC power source, which is configured to prevent poor contact between the DC power output terminals of the detachable DC power source and the AC power input terminals of the DC/AC conversion arrangement and allow the user to install the detachable DC power source properly and easily for good electrical connection.

Another advantage of the invention is to provide a portable power station with detachable DC power source, wherein the total output power capacity of the detachable DC power source is adjustable through the number of the power banks to be installed and the way of electrical connection, in series or in parallel, among the power banks.

Another advantage of the invention is to provide a portable power station with detachable DC power source, wherein multiple pre-charged detachable DC power sources can be carried by the user to prolong the service time of the portable power station.

Another advantage of the invention is to provide a portable power station which provides at least one utility dock for selectively and detachably equipping the portable power station with an additional utility device while supplying power to and/or charging the utility device to support the performance of the portable power station as well as to allow the user to carry and have an additional utility function along with the DC/AC power supply.

According to the present invention, the foregoing and other objects and advantages are attained by a portable power station, comprising:
a reinforcing support frame comprising a mounting panel and two support side panels downwardly extended from two ends of the mounting panel respectively in such a manner that an upper chamber is defined above the mounting panel and a lower chamber is defined between the two support side panels and below the mounting panel;
a DC/AC conversion arrangement, supported by the mounting panel to be positioned in the upper chamber of the reinforcing support frame, being configured to at least convert DC power to AC power and comprising one or more AC power output terminals positioned on a front side of the upper chamber of the reinforcing support frame and at least one DC power input terminal extended to a rear side of the lower chamber of the reinforcing support frame; and
at least a detachable DC power source supported by the reinforcing support frame and received in the lower chamber of the reinforcing support frame in a detachable manner, wherein the detachable DC power source comprises a DC power supply terminals provided on a rear side thereof and configured to electrically connect with the DC power input terminal of the DC/AC conversion arrangement when the detachable DC power source is received in the lower chamber of the reinforcing support frame.

In one embodiment, the portable power station comprises a temporary power supply such as a battery for supplying temporary power during replacing the detachable DC power source, an inverter configured to convert the DC power supplied by the detachable DC power source to AC power output power supply via the AC power output terminals, a rectifier configured to be connected to an external power supply to charge the temporary battery and the detachable DC power source connected thereto, and a control circuit configured to control an operation of the inverter, the rectifier and the temporary battery, wherein the control circuit, the inverter, the rectifier, and the temporary battery are mounted on the mounting panel and received in the upper chamber to constitute the DC/AC conversion arrangement.

In one embodiment, the detachable power station further comprises two air ventilating side covers respectively mounted to the two support side panels and upwardly extended to cover two sides of the DC/AC conversion arrangement to define two side walls of the upper chamber, and a top cover configured to be mounted between the two air ventilating side covers to define a top wall of the upper chamber and cover the DC/AC conversion arrangement, wherein since both the DC/AC conversion arrangement and the detachable DC power source are supported by the reinforcing support frame, the air ventilating side covers and the top cover are made of light weight material for ornamental decoration and sheltering the DC/AC conversion arrangement.

In one embodiment, the reinforcing support frame is configured to support both the DC/AC conversion arrangement and the detachable DC power source to minimize an overall weight and installation space of the portable power station and facilitate heat dissipation conforming to the fluid dynamics phenomenon.

In one embodiment, the reinforcing support frame is configured to support both the DC/AC conversion arrangement and the detachable DC power source to shorter the electrical connection therebetween and reduce the heat transfer of the DC/AC conversion arrangement to the detachable DC power source.

In one embodiment, the detachable DC power source is positioned and supported opposing to a direction of the heat flow of the heat generated during operation of the DC/AC conversion arrangement.

In one embodiment, an air insulation layer is formed between the DC/AC conversion arrangement positioned in the upper chamber and mounted on the mounting panel and the detachable DC power source detachably supported in the lower chamber of the reinforcing support frame.

In one embodiment, the detachable DC power source comprises a housing made of thermal conducting material such as metal or light weight alloy defining a receiving cavity therein and two or more DC power banks electrically connected to the DC power supply terminals, selectively in series or in parallel manner, to supply DC power, wherein one or more DC power output terminals are on a front surface of the housing. In one embodiment, the front panel of the housing is openable to access the receiving cavity so as to take out or install the power banks.

In one embodiment, the AC power output terminals are provided on a front side of the reinforcing support frame that not only provides a rigid support for the pulling force applied during the unplugging of the electrical plug of external AC electric appliance but also arranges both the AC power output terminals and the DC power output terminals, which are spacedly provided below the AC power output terminals, on the same side of the portable power station in a convenient manner, allowing the user to conveniently operate and control at the same side of the portable power station.

In one embodiment the power banks are received in the housing of the detachable DC power source in a detachable manner such that the DC power banks are able to be detached from the detachable DC power source for external charging and external portable use to supply DC power to external electrical appliances independently.

In one embodiment, a plurality of power bank docks are provided in the housing of the detachable DC power source to receive the power banks respectively in a detachable manner.

In one embodiment, the number and power capacity of the power banks to be received in the detachable DC power source is determinable to the user to manage and control the weight of the portable power station to meet the user's actual requirement and usage environment.

In one embodiment, the portable power station further comprises an electrical connector comprising a female connector and a male connector, wherein the female connector provided on a rear panel of the housing of the detachable DC power source and electrically connected with DC power output terminals of the power banks installed in the housing of the detachable DC power source, wherein the male connector is mounted to a underside of the mounting panel of the reinforcing support frame and extended to a rear portion of lower chamber in such a manner that, when the detachable DC power source is received in the lower chamber, the female connector is able to be completely connected with the male connector so as to electrically connect the power banks of the detachable DC power source with the DC/AC conversion arrangement.

In one embodiment, the electrical connector is a suspension type electrical connector which the male and female connectors will only connect with each other when the DC power output terminals and the DC power input terminals of the DC/AC conversion arrangement are completely connected with each other electrically.

In one embodiment, the portable power station provides at least one utility dock which provides an electrical connection terminal for electrically connected with an additional utility device while it is fittingly received in the utility dock so as to supply power to the utility device and/or charge the utility device. The utility device can be a display device to display operation information such as the level of remaining power supply of the detachable DC power source, the speed of the power consuming, alert for charging and/or replacing the detachable DC power source, and etc. The utility device can be an audio device, a lighting device, an additional power bank, a GPS, a smart device, and the like that can support the performance of the portable power station. The utility device can be wirelessly communicated with the portable power station when it is detached therefrom.

In one embodiment, a magnetic attraction unit can be provided at the utility dock to allow the utility device to be easily and accurately received in the utility dock to ensure the best electrical connection. In one embodiment, the electrical connection between the utility dock and the utility device can be configured through magnetic attracting electrical terminals.

These and other objectives, features, and advantages of the present invention will become apparent from the following detailed description, the accompanying drawings, and the appended claims.

### BRIEF DESCRIPTION OF THE DRAWINGS

FIG. 1A is a schematic view of a conventional portable power station.

FIG. 1B is a circuit diagram of the conventional portable power station as shown in FIG. 1A.

FIG. 2 is an exploded view of another conventional portable power station.

FIG. 3 is a perspective view of another conventional portable power station.

FIG. 4 is an exploded view of a portable power station according to a preferred embodiment of the present invention.

FIG. 5A is a perspective view of the portable power station according to the above preferred embodiment of the present invention.

FIG. 5B is a partial exploded perspective view of the portable power station according to the above preferred embodiment of the present invention, illustrating an arrangement of the AC power output sockets and the DC power output terminals.

FIG. 6 is a partial exploded perspective view of the portable power station according to the above preferred embodiment of the present invention, illustrating the DC/AC conversion arrangement.

FIG. 7 is a sectional view of the portable power station according to the above preferred embodiment of the present invention.

FIG. 8 is a partial exploded perspective view of the portable power station according to the above preferred embodiment of the present invention, illustrating the housing of the detachable DC power source.

FIG. 9 is a partial exploded perspective view of the portable power station according to the above preferred embodiment of the present invention, illustrating the detachable and electrical connection between the detachable DC power source and the DC/AC conversion arrangement.

FIGS. 10A and 10B are partial exploded perspective views of the portable power station according to the above preferred embodiment of the present invention, illustrating the utility dock thereof.

FIG. 11 is a block diagram of the portable power station according to the above preferred embodiment of the present invention.

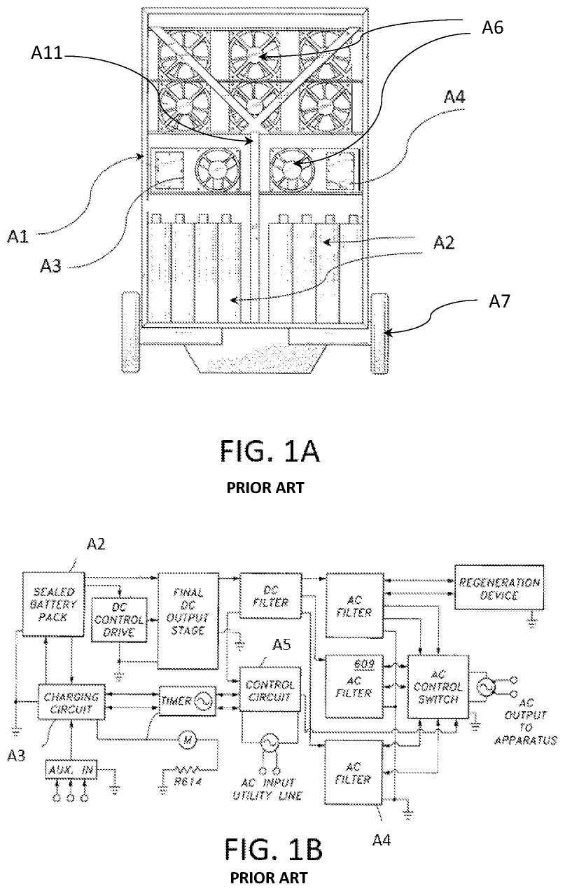

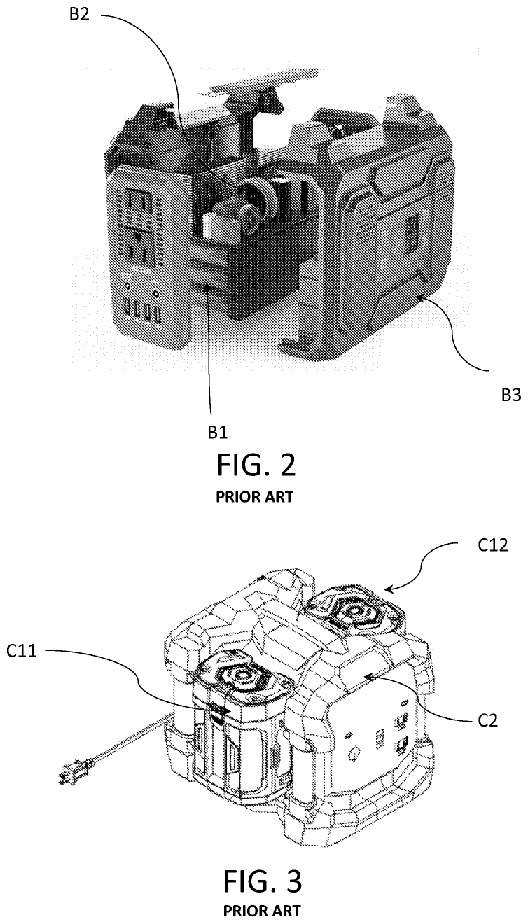

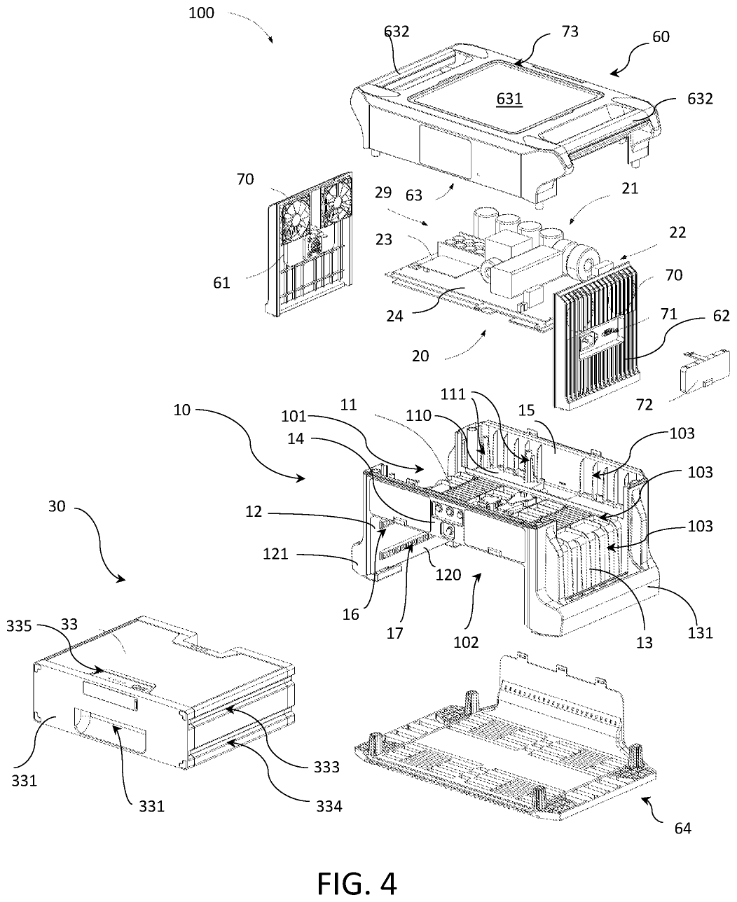

The drawings, described above, are provided for purposes of illustration, and not of limitation, of the aspects and features of various examples of embodiments of the invention described herein. The drawings are not intended to limit the scope of the claimed invention in any aspect. For simplicity and clarity of illustration, elements shown in the drawings have not necessarily been drawn to scale and the dimensions of some of the elements may be exaggerated relative to other elements for clarity.

### DETAILED DESCRIPTION OF THE PREFERRED EMBODIMENT

The following description is disclosed to enable any person skilled in the art to make and use the present invention. Preferred embodiments are provided in the following description only as examples and modifications will be apparent to those skilled in the art. The general principles defined in the following description would be applied to other embodiments, alternatives, modifications, equivalents, and applications without departing from the spirit and scope of the present invention.

It will be appreciated that numerous specific details are set forth in order to provide a thorough understanding of the exemplary embodiments described herein. However, it will be understood by those of ordinary skill in the art that the embodiments described herein may be practiced without these specific details. In other instances, well-known methods, procedures and components have not been described in detail so as not to obscure the embodiments described herein. Further, this description is not to be considered as limiting the scope of the embodiments described herein in any way, but rather as merely describing implementation of the one or more embodiments described herein.

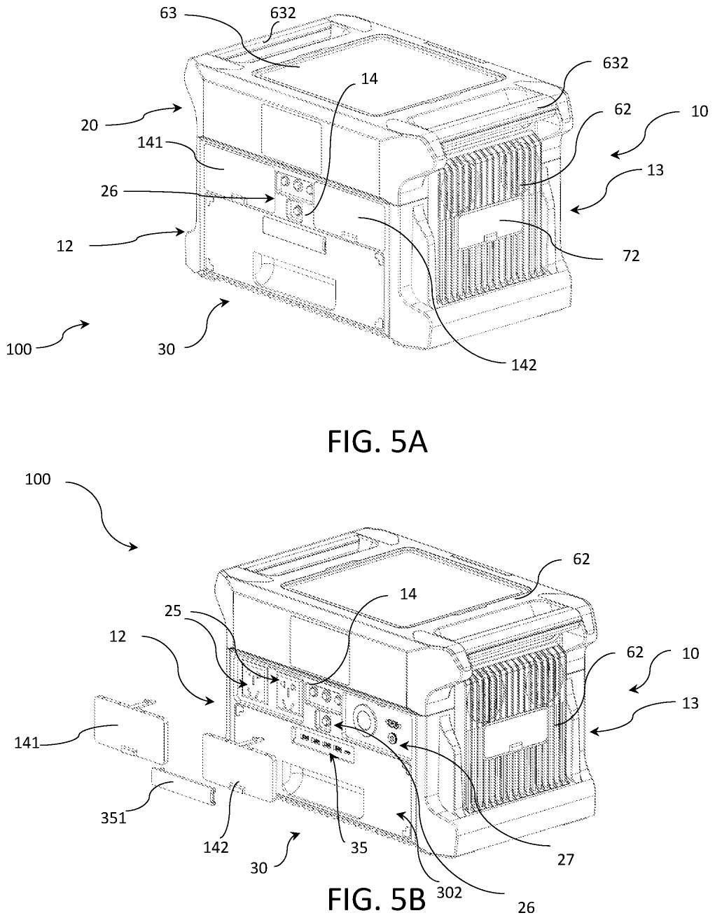

Referring to FIG. 4 to FIG. 11, a portable power station 100 according to a preferred embodiment of the present invention is illustrated, wherein a main inventive concept of the present invention is to provide a compact in size and lighter in weight portable power station 100 to convert DC power to AC power supply while maintaining a good heat dissipation configuration. The portable power station 100 comprises a reinforcing support frame 10 comprises a mounting panel 11 and two support side panels 12, 13 perpendicularly and downwardly extended from two ends of the mounting panel 11 respectively such that an upper chamber 101 is defined above the mounting panel 11 and a lower chamber 102 is defined between the two support side panels 12, 13 and below the mounting panel 11, as shown in FIG. 4.

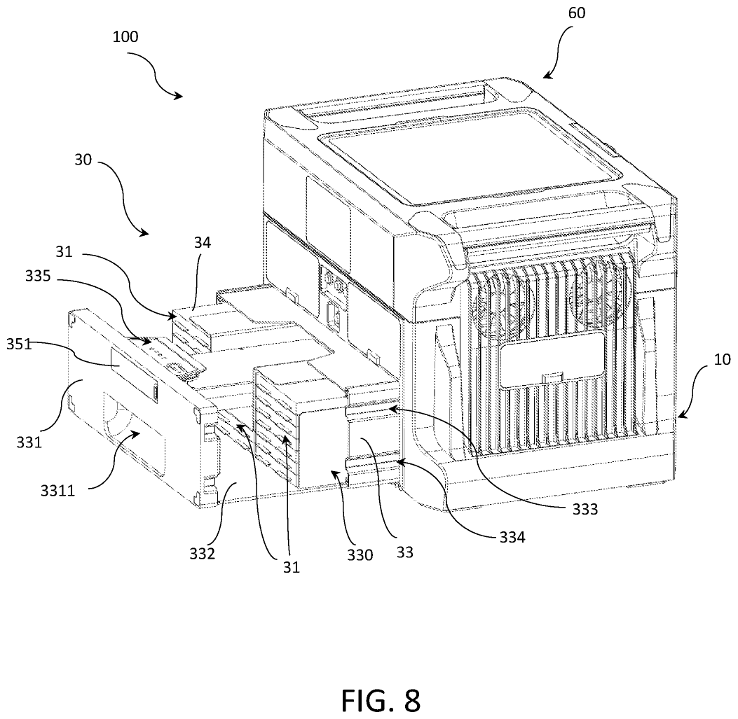

Referring to FIG. 4 and FIG. 7, the reinforcing support frame 10 is preferred to be made to form a II shape integral body. According to the preferred embodiment, the reinforcing support frame 10 further comprises a front panel 14 and a rear panel 15 integrally and upwardly extended formed a front end and a rear end of the mounting panel 11 that defines the upper chamber 101 therebetween above the mounting panel 11. Each of the two support side panels 12, 13 forms an enlarged base 121, 131 outwardly extended to enlarge a bottom contact surface so as for steadily supporting the reinforcing support frame 10 in a balanced manner on a supporting surface such as ground or tabletop. The mounting panel 11 and the front and rear panels 14, 15 form a U shape configuration while the mounting panel 11 and the two right and left support side panels 12, 13 form a II shape configuration such that the reinforcing support frame 11 constructs a rigid and reinforced framework for supporting forces applied in all directions as a skeleton structure of the portable power station 100.

The reinforcing support frame 10 can be made of metal, alloy or plastic by molding to provide a plurality of reinforcing ribs 103 on the mounting panel 11, the two support side panels 12, 13, the front panel 14, and the rear panel 15 respectively. On the mounting panel 11, a plurality of support posts 111 is spacedly and upwardly protruded from a top surface 110 thereof. Two pairs of rails 16, 17 are parallelly mounted on inner surfaces 120, 130 of the two support side panels 12, 13 respectively.

Referring to FIG. 4, FIGS. 7-9 and FIG. 11, in order to convert DC power to AC power, an inverter 21 is supported on top of the mounting panel 11 of the reinforcing support frame 10 of the portable power station 100 which is adapted to electrically connect with a DC power source for converting the low voltage DC power supplied by the DC power source to a high voltage AC power. In addition, in order to charge the DC power source connected to the inverter 21, a charging circuit such as a rectifier 22 is also supported on top of the mounting panel 11 of the reinforcing support frame 10, which is electrically connected to the DC power source through a control circuit 23 that is electrically connected with the inverter 21 and the rectifier 22. According to the preferred embodiment of the present invention, the inverter 21, the rectifier 22 and the control circuit 23 are mounted on a mother board 24 to form a DC/AC conversion arrangement 20, as shown in FIG. 4.

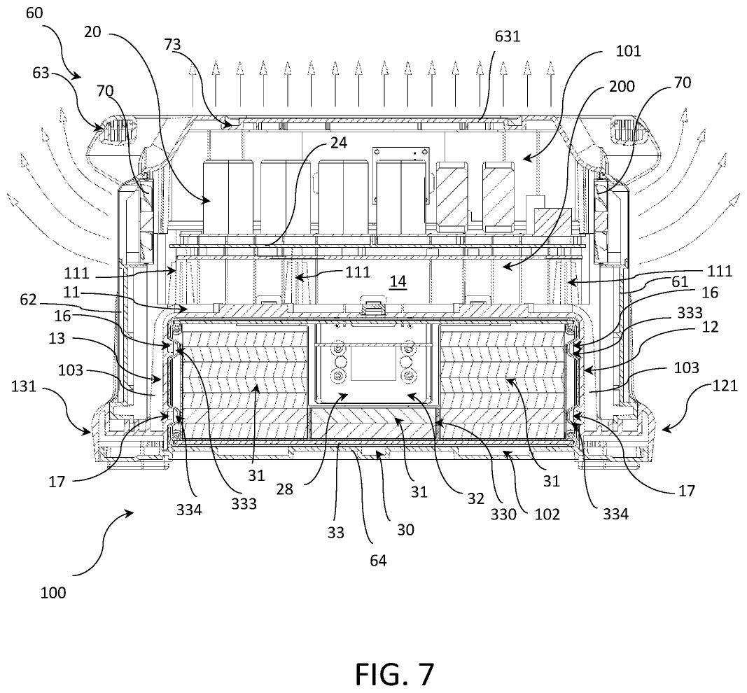

The DC/AC conversion arrangement 20 is mounted on the support posts 111 so as to be supported on top of the mounting panel 11 of the reinforcing support frame 10, as shown in FIG. 4 and FIG. 7, and defines an insulation layer 200 between the mother board 24 of the DC/AC conversion arrangement 20 and the mounting panel 11, as shown in FIG. 6 and FIG. 7. The insulation layer 200 is an air layer provides a good thermal insulation from the heat generated by the DC/AC conversion arrangement 20 transferring from the upper chamber 101 to the lower chamber 102. According to the fluid dynamics phenomenon, heat energy trends to flow upwards and to where having a lower temperature. Therefore, the heat generated during the operation of the DC/AC conversion arrangement 20, especially the inverter 21, mounted in the upper chamber 101 above the mounting panel 11 flows upwards and sidewards, as shown in FIG. 6, while the insulation layer 200 substantially insulates the heat to flow and transfer to the lower chamber 102 below the mounting panel 11, as shown in FIG. 7.

In other embodiments, an insulation material (not shown) can be placed in the air insulation layer 200 for further insulation requirement. It is especially valuable for heavy loading high voltage power station according to the present invention.

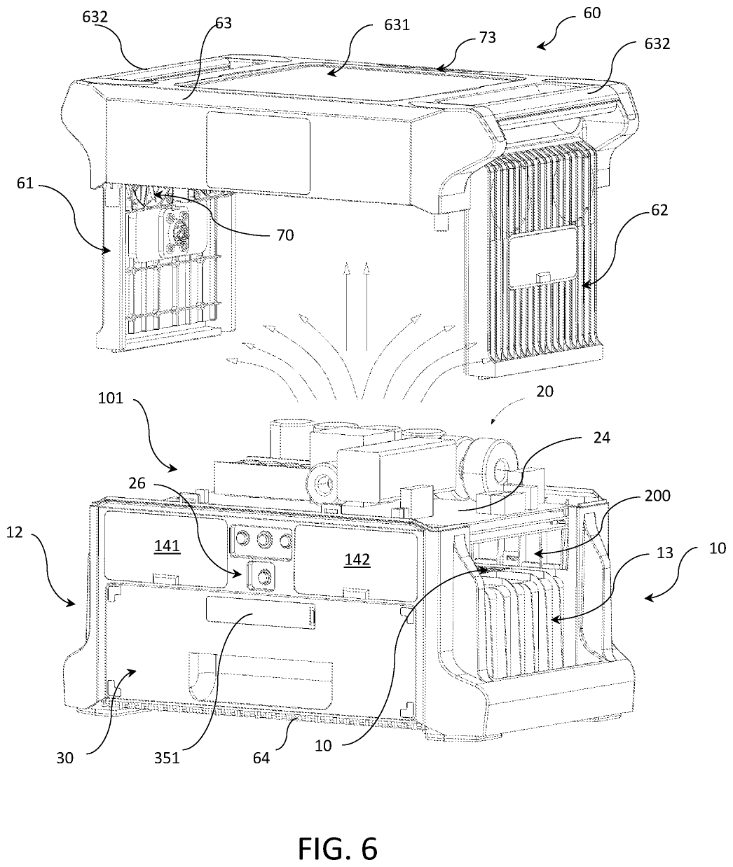

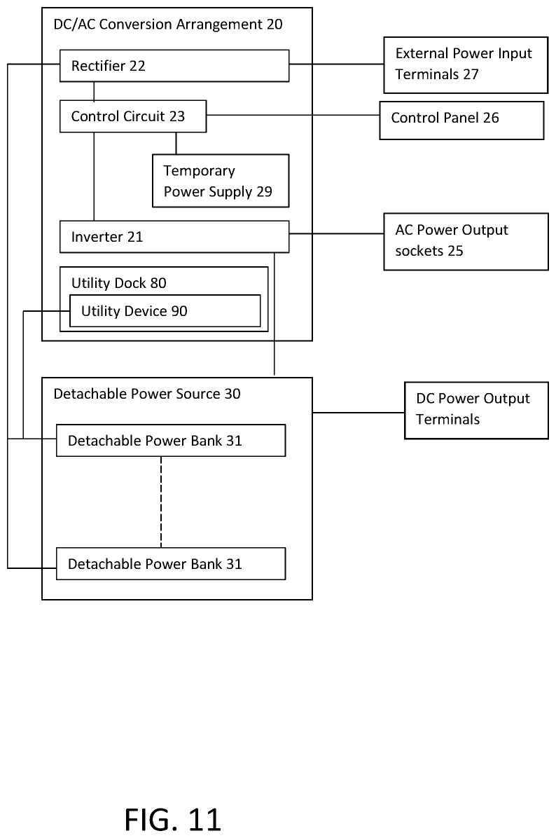

Referring to FIG. 5B and FIG. 11, the DC/AC conversion arrangement 20, which is supported by the mounting panel 11 to be positioned in the upper chamber 101 of the reinforcing support frame 10, is configured to at least convert the DC power to AC power and comprises one or more AC power output terminals 25 positioned on a front side of the upper chamber 101 of the reinforcing support frame 10. According to the preferred embodiment, the one or more AC power output terminals 25 are embodied as AC power output sockets mounted on the front panel 14 of the reinforcing support frame 10 and configured to output AC power supply. The DC/AC conversion arrangement 20 further comprises a control panel 26 provided on the front panel 14 of the reinforcing support frame 10 and configured for the user to control and operate the DC/AC conversion arrangement 20, such as switching between an inversion mode to actuate the inverter 21 and a charging mode to actuate the rectifier 22, one or more external power input terminals 27 for one or more electrical plugs of an external AC power supply and/or an external DC power supply to electrically connect therewith for charging. Two covers 141, 142 are provided to detachably cover the AC power output sockets 25 and the external input terminals 27 when they are not in use, as shown in FIG. 5A.

The user may simply connect an external DC power source to an external DC power input terminal of the external input terminals 27 to supply DC power to the inverter 21 of the DC/AC conversion arrangement 20 for AC power output at the AC power output terminals 25.

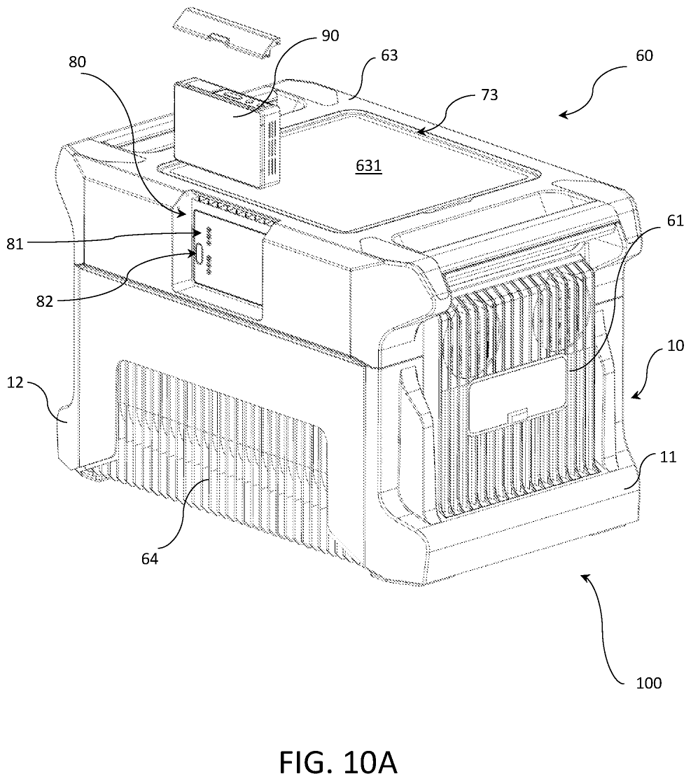

Preferably, referring to FIG. 4, FIGS. 7-9 and FIG. 11, the portable power station 100 further comprises a detachable DC power source 20 configured to be supported by the reinforcing support frame 10 and received in the lower chamber 102 of the reinforcing support frame 10 in a detachable manner, wherein the detachable DC power source 20 comprises two or more DC power banks 31 and a DC power supply terminals 32 provided on a rear side 301 thereof (as shown in FIG. 9) and one or more DC power output terminals 35 provided on a front side 302 thereof (as shown in FIG. 5B). Correspondingly, the DC/AC conversion arrangement 20, as shown in FIG. 9, further comprises a DC power input terminal 28 such that the DC power supply terminal 32 of the detachable DC power source 30 are configured to electrically connect with the DC power input terminal 28 of the DC/AC conversion arrangement 20 when the detachable DC power source 10 is received in the lower chamber 102 of the reinforcing support frame 10, as shown in FIG. 7.

The detachable DC power source 30 comprises a housing 33, preferably made of thermal conducting material such as metal or light weight alloy, defining a receiving cavity 330 therein, and a plurality of power bank docks 34 affixed in the receiving cavity 330. The two or more DC power banks 31 are held in the receiving cavity 330 by the power bank docks 34 and electrically connected to the DC power supply terminals 32, selectively in series or in parallel manner, to supply DC power. The power bank docks 34 are also preferred to be made of thermal conducting material and functions as heat sink and a reinforcing frame to support the housing. Accordingly, the heat generated from the DC power banks 31 during operation thereof can be dissipated through the housing 33 to outside.

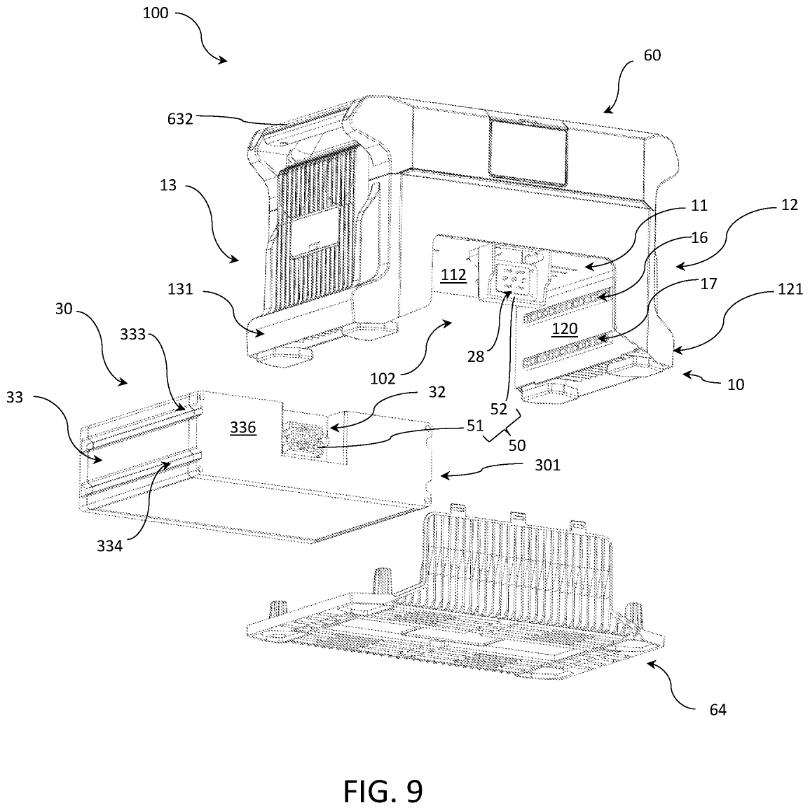

According to the preferred embodiment, as shown in FIG. 8, the detachable DC power source 30 further comprises a front drawer panel 331 and a drawer board 332 rearwardly extended from the front drawer panel 331 to slidably insert into the receiving cavity 330 and the power bank docks 34 are affixed on the drawer board 332. Accordingly, the two or more DC power banks 31 held by the power bank docks 34 can be accessed and reached from outside after pulling out the front drawer panel 331 and the drawer board 332 from the receiving cavity 330 of the housing 33 for replacement of the DC power banks 31. A handle 3311 embodied as a handle slot can be provided on the front drawer panel 331 that enables the user to pull to disconnect the electrical connection the DC power supply terminals 32 of the detachable DC power source 30 from the DC power input terminals 28 of the DC/AC conversion arrangement 20, and detach the detachable DC power source 30 from the lower chamber 102 of the reinforcing support frame 10, as shown in FIG. 8 and FIG. 9.

Furthermore, a secure lock unit 335 is provided on the front drawer panel 331 so that user may selectively lock the front drawer panel 331 to the housing 33 as shown in FIG. 4 and unlock the front drawer panel 331 by pulling out the drawer board 332 out of the receiving cavity 330 of the housing 33 for power banks arrangement and replacement. The user may select the desired number and power capacity of the DC power banks 31 to be installed in the housing 33 so as to determine the weight and DC power output capacity of the detachable DC power source 30 to be carried by the portable power station 100 according to the needs of the user and the working environment.

Referring to FIGS. 4 and 7-9, two pairs of rail slots 333, 334 are parallelly indented in two sides of the housing 33 which are fittingly sized and shaped to allow the two pairs of rails 16, 17 mounted on the inner surfaces 120, 130 of the two support side panels 12, 13 to slide in so as to support the housing 33 of the detachable DC power source 30 in the lower chamber 102 via the two support side panels 12, 13 of the reinforcing support frame 10, as shown in FIG. 7. The housing 33 may be installed with as many the DC power banks 31 as possible to supply as much power capacity as possible and the housing 33 also fills up the lower chamber 102 to form a further reinforcing to the reinforcing support frame 10 and a lower weight portion of the portable power station 100.

The one or more DC power output terminals 35 embodied as USB sockets are provided on the front drawer panel 331 of the housing 33 and electrically connected to at least one of the DC power banks 31 received in the housing 33 of the detachable DC power source 30, such that the detachable DC power source 30 can be used to supply DC power independently even it is not installed with the portable power station 100. It is appreciated that when the detachable DC power source 30 is installed in the lower chamber 102 of the reinforcing support frame 10 to form the portable power station 100, the one or more DC power output terminals 35 are provided on the same front side of the portable power station 100 below the AC power output terminals 25, as shown in FIG. 5B, so as to facilitate the user to select and consume DC and AC power supply. A cover 351 can be provided to cover and protect the DC power output terminals 35 when they are not in use.

In other words, the AC power output terminals 25 are provided on the front side of the reinforcing support frame 10 that not only provide a rigid support for the pulling force applied during the unplugging of the electrical plug of external AC electric appliance but also arrange both the AC power output terminals 25 and the DC power output terminals 35, which are spacedly provided below the AC power output terminals 25, on the same side of the portable power station 100 in a convenience manner, allowing the user to conveniently operate and control at the same side of the portable power station 100.

According to the preferred embodiment of the present invention, it is appreciated that the user may carry the portable power station 100 with additional detachable DC power sources 30 so that when the installed detachable DC power source 30 drains out of power, the user may simply detach the drained DC power source 30 and replace a fully charged DC power source 30 in the lower chamber 102 of the portable power station 100 to continuously supply AC power. Therefore, the overall weight of the portable power station 100 can be relatively light since extra DC power supply, i.e. multiple detachable DC power sources 30, can be carried separately, that facilitates the user to move the portable power station 100 around and allows the portable power station 100 to be designed in a more compact size and shape. In other words, the number and power capacity of the DC power banks 31 to be received in the detachable DC power source 10 is determinable to the user to manage and control the weight of the portable power station 100 to meet the user's actual requirement and usage environment.

In order to provide temporary power supply during the replacement of the detachable DC power source 30 of the portable power station 100, the DC/AC conversion arrangement 20 is preferred to further comprise a temporary power supply 29, embodied as one or more temporary batteries, as shown in FIG. 4 and FIG. 11, for supplying temporary power for the following conditions:
(1) when the installed detachable DC power source 30 is drained out, provide temporary power supply for audio and/or lighting alert for a predetermined period of time to remind the user to replace another charged detachable DC power source 30;
(2) to supply temporary power for converting to AC power supply while the detachable DC power source 30 is detached and before another fully charged detachable DC power source 30 is replaced and electrically connected with the DC/AC conversion arrangement 20; and
(3) to supply temporary power when the installed detachable DC power source 30 is detected by the control circuit 23 malfunctioning for audio and/or lighting warning signals to call attention to the user.

Accordingly, the portable power station 100 of the present invention is designed and arranged to provide both low voltage DC and high voltage AC uninterrupted power supply.

Referring to FIG. 9, the portable power station 100 further comprises an electrical connector 50 comprising a female connector 51 and a male connector 52, wherein the female connector 51 provided on a rear panel 336 of the housing 33 of the detachable DC power source 30 and electrically connected with DC power output terminals 32 of the DC power banks 31 installed in the housing 33 of the detachable DC power source 30. The male connector 52, which is electrically connected with the DC power input terminals 28 of the DC/AC conversion arrangement 20, is mounted to a underside 112 of the mounting panel 11 of the reinforcing support frame 10 and extended to a rear portion of lower chamber 102 in such a manner that, when the detachable DC power source 30 is received in the lower chamber 102, the female connector 51 is able to be completely connected with the male connector 52 so as to electrically connect the DC power banks 31 of the detachable DC power source 30 with the DC/AC conversion arrangement 20.

According to the preferred embodiment, the electrical connector 50 is a suspension type electrical connector which male and female connectors 51, 52 will only connect with each other when the DC power output terminals 32 and the DC power input terminals 28 of the DC/AC conversion arrangement 20 are completely connected with each other electrically.

It is worth to mentioning that the rectifier 22 of the DC/AC conversion arrangement 20 is configured to be connected to an external power supply via the external power input terminal 27 to charge the temporary power supply 29 and even the installed detachable DC power source 30 by operating the control circuit 23 to select the rectifier 22 to function.

Since the reinforcing support frame 10 substantially supports the weight of the DC/AC conversion arrangement 20 and the detachable DC power source 30, the portable power station 100 of the present invention does not required a heavy and strengthened enclosure housing but simplifies the supporting configuration by the reinforcing support frame 10, cover panels made of light weight material can be used to cover and shelter the DC/AC conversion arrangement 20 and the detachable DC power source 30 from reaching outside and for ornamental decoration. Referring to FIG. 4 and FIG. 5A, the detachable power station 100 further comprises two air ventilating side covers 61, 62 respectively mounted to the two support side panels 12, 13 and upwardly extended to cover two sides of the DC/AC conversion arrangement 20 to define two side walls of the upper chamber 101, and a top cover 63 configured to be mounted between the two air ventilating side covers 61, 62 to define a top wall of the upper chamber 101 and cover the DC/AC conversion arrangement 20. The ventilating side covers 61, 62 are embodied as grids having ventilation through slots according to the preferred embodiment of the present invention to facilitate air ventilation, wherein the lower temperature outside the portable power station 100 will enhance the heat generated from the DC/AC conversion arrangement 20 to flow out through the air ventilation side covers 61, 62. It is worth mentioning that, to person skilled in the art, the two air ventilating side covers 61, 62 and the top cover 63, which are combined to form a U-shaped shelter cover 60 to cover the upper chamber 101 and the DC/AC conversion arrangement 20 therein, can be replaced by an integral U-shape shelter cover.

Although the heat generated by the DC/AC conversion arrangement 20 during the converting of the DC power supply to AC power supply and the charging of the temporary power supply 29 and the DC power banks 31 of the detachable power source 30 is trends to flow upwards and sidewards, referring to FIG. 4. FIG. 6 and FIG. 7, air flow driving devices 70 are preferred to be mounted to the two air ventilating side covers 61, 62 respectively, which are embodied as electric fans for generating an in-to-out air flow in the upper chamber 101, to drive the air inside the upper chamber 101 out through the air ventilating side covers 61, 62 so as to facilitate the heat dissipation in the upper chamber 101. In addition, on the top cover 63, a surrounding air ventilating channel 73 is formed around a top portion 631 to facilitate the heat in the upper chamber 101 to dissipate upwardly outside therethrough, as shown in FIG. 7. According to the preferred embodiment, two handle bars 632 are formed at left and right sides of the top cover 63 respectively for the user to hand carry the portable power station 100.

On one of the air ventilation side covers 61, 62, one or more additional power sockets 71 are provided for external power input or power output. A cover 72 is also preferred to be provided to cover the additional power sockets 71 when not being used.

It is worth mentioning that, the reinforcing support frame 10 is configured to support both the DC/AC conversion arrangement 20 and the detachable DC power source 30 on the upper side and lower side of the mounting panel 11 while the AC power output terminals 25 are provided on the front panel 14 so that not an overall weight and installation space of the portable power station 100 are minimized and the electrical connection between the DC/AC conversion arrangement and the detachable DC power source as well as the AC power output terminals 25 are shortened that also reduces the heat transfer of the DC/AC conversion arrangement to the detachable DC power source. In addition, by means of the reinforcing support frame 10, the detachable DC power source 30 is positioned and supported opposing to a direction of the heat flow of the heated generated during operation of the DC/AC conversion arrangement 20.

Referring to FIG. 4, FIG. 7 and FIG. 9, in order to further protect the detachable DC power source 30, a L-shape bottom cover 64 is preferred to be mounted between bottom ends of the two support side panels 12, 13 to cover a bottom and a rear side of the detachable DC power source 30 installed in the lower chamber 102 and to enclose the lower chamber 102.

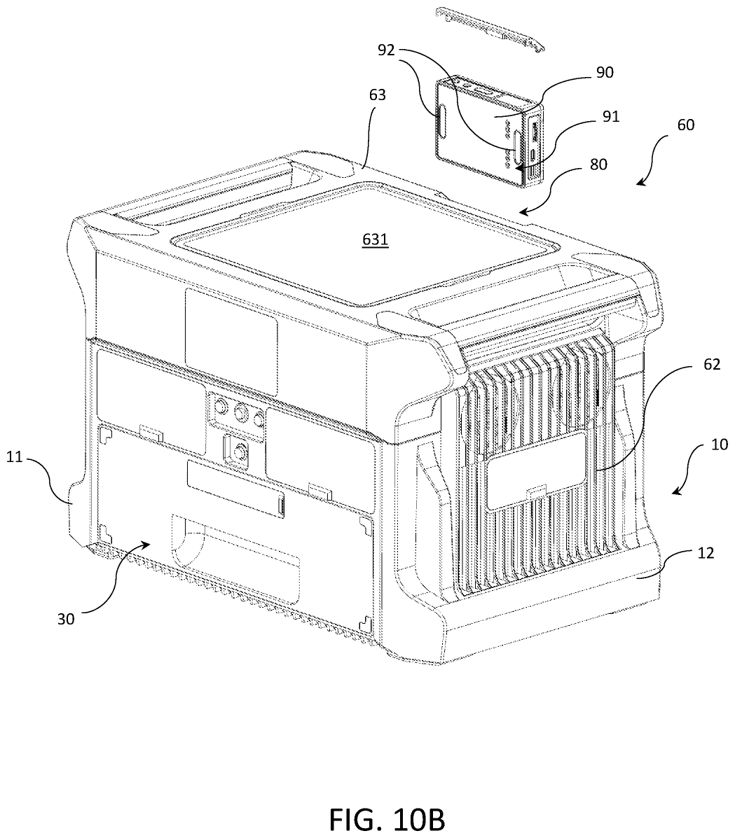

Referring to FIG. 10A to FIG. 11, according to preferred embodiment of the present invention, the portable power station 100 provides at least one utility dock 80 which provides an electrical connection terminal 81 for electrically connected with an additional utility device 90 while it is fittingly received in the utility dock 80 so as to supply power to the utility device 90 and/or charge the utility device 90. The utility device 90 can be a display device to display operation information such as the level of remaining power supply of the detachable DC power source 30, the speed of the power consuming, alert for charging and/or replacing the detachable DC power source 30, and etc. The utility dock 80 is embodied as an indented slot formed at a rear side of the top cover 63, as shown in FIG. 10A. The utility device 90 can be an audio device, a lighting device, an additional power bank, a GPS, a smart device, and the like, that is shaped and sized to fittingly received in the utility dock 80 and configured to support the performance of the portable power station 100. The utility device 90 can be wirelessly communicating with the portable power station 100 to function independently when it is detached therefrom. The utility device 90 can be electrically connected with the detachable DC power source 30 through the control circuit 23 of the DC/AC conversion arrangement 20 so as to be charged by the detachable DC power source 30 when it is docked in the utility dock 80 while an electrical connection terminal 91 of the utility device 90 as shown in FIG. 10B is electrically connected with the electrical connection terminal 81 provided on the utility dock 80.

According to the preferred embodiment, a pair of magnetic attraction units 82, 92 can be provided at the utility dock 80 and the utility device 90 respectively to allow the utility device 90 to be easily and accurately received in the utility dock 80 to ensure the best electrical connection. Preferably, the electrical connection between the utility dock 80 and the utility device 90 can be configured through magnetic attracting electrical terminals.

One skilled in the art will understand that the embodiment of the present invention as shown in the drawings and described above is exemplary only and not intended to be limiting.

It will thus be seen that the objects of the present invention have been fully and effectively accomplished. The embodiments have been shown and described for the purposes of illustrating the functional and structural principles of the present invention and is subject to change without departure from such principles. Therefore, this invention includes all modifications encompassed within the spirit and scope of the following claims.

What is claimed is:

1. A portable power station, comprising:
a reinforcing support frame comprising a mounting panel and two support side panels downwardly extended from two ends of said mounting panel respectively in such a manner that an upper chamber is defined above said mounting panel and a lower chamber is defined between said two support side panels and below said mounting panel;
a DC/AC conversion arrangement, supported by said mounting panel to be positioned in said upper chamber of said reinforcing support frame, being configured to at least convert a DC power to an AC power and comprising one or more AC power output terminals positioned on a front side of said upper chamber of said reinforcing support frame and at least one DC power input terminal extended to a rear side of said lower chamber of said reinforcing support frame; and
at least a detachable DC power source supported by said reinforcing support frame and received in said lower chamber of said reinforcing support frame in a detachable manner, wherein said detachable DC power source comprises two or more DC power banks and a DC power supply terminal provided on a rear side thereof and configured to electrically connect said DC power banks and said DC power input terminal of said DC/AC conversion arrangement when said detachable DC power source is received in said lower chamber of said reinforcing support frame, thereby said detachable DC power source is positioned and supported opposing to a direction of a flow of heat generated during an operation of said DC/AC conversion arrangement.

2. The portable power station, as recited in claim 1, further comprising a temporary power supply in said upper chamber for supplying temporary power during replacing said detachable DC power source.

3. The portable power station, as recited in claim 2, wherein said DC/AC conversion arrangement comprises:
an inverter configured to convert said DC power supplied by said detachable DC power source to said AC power supplying via said AC power output terminals,
a rectifier configured for connecting an external power supply to charge said temporary power supply and said detachable DC power source connected thereto, and
a control circuit configured to control an operation of said inverter, said rectifier and said temporary power supply, wherein said control circuit, said inverter, said rectifier, and said temporary battery are supported on said mounting panel and received in said upper chamber to constitute said DC/AC conversion arrangement.

4. The portable power station, as recited in claim 1, further comprising two air ventilating side covers respectively mounted to said two support side panels and upwardly extended to cover two sides of said DC/AC conversion arrangement to define two side walls of said upper chamber, and a top cover configured to be mounted between said two air ventilating side covers to define a top wall of said upper chamber and cover said DC/AC conversion arrangement.

5. The portable power station, as recited in claim 3, further comprising two air ventilating side covers respectively mounted to said two support side panels and upwardly extended to cover two sides of said DC/AC conversion arrangement to define two side walls of said upper chamber, and a top cover configured to be mounted between said two air ventilating side covers to define a top wall of said upper chamber and cover said DC/AC conversion arrangement, wherein one or more air flow driving devices are provided on said two side ventilating side covers respectively to generate an air flow from said upper chamber to outside.

6. The portable power station, as recited in claim 1, wherein an insulation layer is formed between said DC/AC conversion arrangement positioned in said upper chamber and supported on said mounting panel and said detachable DC power source detachably supported in said lower chamber of said reinforcing support frame.

7. The portable power station, as recited in claim 3, wherein an insulation layer is formed between said DC/AC conversion arrangement positioned in said upper chamber and supported on said mounting panel and said detachable DC power source detachably supported in said lower chamber of said reinforcing support frame.

8. The portable power station, as recited in claim 5, wherein an air layer is formed between said DC/AC conversion arrangement positioned in said upper chamber and supported on said mounting panel and said detachable DC power source detachably supported in said lower chamber of said reinforcing support frame.

9. The portable power station, as recited in claim 1, wherein said detachable DC power source further comprises a housing defining a receiving cavity therein, wherein said two or more DC power banks are electrically connected to said DC power supply terminals, selectively in series or in parallel manner, to supply DC power, wherein one or more DC power output terminals are provided on a front surface of said housing, such that said DC power output terminals and said AC power output terminals are both available on a same front side of the portable power station.

10. The portable power station, as recited in claim 3, wherein said detachable DC power source further comprises a housing defining a receiving cavity therein, wherein said two or more DC power banks are electrically connected to said DC power supply terminals, selectively in series or in parallel manner, to supply DC power, wherein one or more DC power output terminals are provided on a front surface of said housing, such that said DC power output terminals and said AC power output terminals are both available on a same front side of the portable power station.

11. The portable power station, as recited in claim 5, wherein said detachable DC power source further comprises a housing defining a receiving cavity therein, wherein said two or more DC power banks are electrically connected to said DC power supply terminals, selectively in series or in parallel manner, to supply DC power, wherein one or more DC power output terminals are provided on a front surface of said housing, such that said DC power output terminals and said AC power output terminals are both available on a same front side of the portable power station.

12. The portable power station, as recited in claim 8, wherein said detachable DC power source further comprises a housing defining a receiving cavity therein, wherein said two or more DC power banks are electrically connected to said DC power supply terminals, selectively in series or in parallel manner, to supply DC power, wherein one or more DC power output terminals are provided on a front surface of said housing, such that said DC power output terminals and said AC power output terminals are both available on a same front side of the portable power station.

13. The portable power station, as recited in claim 1, wherein at least a pair of rails is formed on inner surfaces of said two support side panels and at least a pair of rail slots are respectively formed in two sides of said housing of said detachable DC power source to receive said pair of rails respectively so as to slidably receive said detachable DC power source in said lower chamber of said reinforcing support frame.

14. The portable power station, as recited in claim 3, wherein at least a pair of rails is formed on inner surfaces of said two support side panels and at least a pair of rail slots are respectively formed in two sides of said housing of said detachable DC power source to receive said pair of rails respectively so as to slidably receive said detachable DC power source in said lower chamber of said reinforcing support frame.

15. The portable power station, as recited in claim 12, wherein at least a pair of rails is formed on inner surfaces of said two support side panels and at least a pair of rail slots are respectively formed in two sides of said housing of said detachable DC power source to receive said pair of rails respectively so as to slidably receive said detachable DC power source in said lower chamber of said reinforcing support frame.

16. The portable power station, as recited in claim 9, further comprising an electrical connector which comprises a female connector and a male connector, wherein said female connector provided on a rear panel of said housing of said detachable DC power source and electrically connected with said DC power output terminals of said power banks installed in said housing of said detachable DC power source, wherein said male connector is mounted to a underside of said mounting panel of said reinforcing support frame and extended to a rear portion of said lower chamber in such a manner that, when said detachable DC power source is received in said lower chamber, said female connector is able to be completely connected with said male connector so as to electrically connect said DC power banks of said detachable DC power source with said DC/AC conversion arrangement.

17. The portable power station, as recited in claim 10, further comprising an electrical connector which comprises a female connector and a male connector, wherein said female connector provided on a rear panel of said housing of said detachable DC power source and electrically connected with said DC power output terminals of said power banks installed in said housing of said detachable DC power source, wherein said male connector is mounted to a underside of said mounting panel of said reinforcing support frame and extended to a rear portion of said lower chamber in such a manner that, when said detachable DC power source is received in said lower chamber, said female connector is able to be completely connected with said male connector so as to electrically connect said DC power banks of said detachable DC power source with said DC/AC conversion arrangement.

18. The portable power station, as recited in claim 11, further comprising an electrical connector which comprises a female connector and a male connector, wherein said female connector provided on a rear panel of said housing of said detachable DC power source and electrically connected with said DC power output terminals of said power banks installed in said housing of said detachable DC power source, wherein said male connector is mounted to a underside of said mounting panel of said reinforcing support frame and extended to a rear portion of said lower chamber in such a manner that, when said detachable DC power source is received in said lower chamber, said female connector is able to be completely connected with said male connector so as to electrically connect said DC power banks of said detachable DC power source with said DC/AC conversion arrangement.

19. The portable power station, as recited in claim 12, further comprising an electrical connector which comprises a female connector and a male connector, wherein said female connector provided on a rear panel of said housing of said detachable DC power source and electrically connected with said DC power output terminals of said power banks installed in said housing of said detachable DC power source, wherein said male connector is mounted to a underside of said mounting panel of said reinforcing support frame and extended to a rear portion of said lower chamber in such a manner that, when said detachable DC power source is received in said lower chamber, said female connector is able to be completely connected with said male connector so as to electrically connect said DC power banks of said detachable DC power source with said DC/AC conversion arrangement.

20. The portable power station, as recited in claim 1, further comprising at least one utility dock which provides an electrical connection terminal for electrically connected with an additional utility device while the utility device is fittingly received in said utility dock so as to supply power to the utility device and to charge the utility device.

21. The portable power station, as recited in claim 20, wherein a magnetic attraction unit is provided at said utility dock to enable the utility device to be accurately received in said utility dock to ensure electrical connection therebetween.

22. The portable power station, as recited in claim 8, further comprising at least one utility dock which provides an electrical connection terminal for electrically connected with an additional utility device while the utility device is fittingly received in said utility dock so as to supply power to the utility device and to charge the utility device, wherein a magnetic attraction unit is provided at said utility dock to enable the utility device to be accurately received in said utility dock to ensure electrical connection therebetween.

23. The portable power station, as recited in claim 12, further comprising at least one utility dock which provides an electrical connection terminal for electrically connected with an additional utility device while the utility device is fittingly received in said utility dock so as to supply power to the utility device and to charge the utility device, wherein a magnetic attraction unit is provided at said utility dock to enable the utility device to be accurately received in said utility dock to ensure electrical connection therebetween.

24. The portable power station, as recited in claim 15, further comprising at least one utility dock which provides an electrical connection terminal for electrically connected with an additional utility device while the utility device is fittingly received in said utility dock so as to supply power to the utility device and to charge the utility device, wherein a magnetic attraction unit is provided at said utility dock to enable the utility device to be accurately received in said utility dock to ensure electrical connection therebetween.

25. The portable power station, as recited in claim 19, further comprising at least one utility dock which provides an electrical connection terminal for electrically connected with an additional utility device while the utility device is fittingly received in said utility dock so as to supply power to the utility device and to charge the utility device, wherein a magnetic attraction unit is provided at said utility dock to enable the utility device to be accurately received in said utility dock to ensure electrical connection therebetween.
